(19) United States
(12) Patent Application Publication
(10) Pub. No.: US 2015/0032406 A1
(43) Pub. Date: Jan. 29, 2015

(54) METHOD AND DEVICE FOR OPTIMIZATION OF A PULSE SEQUENCE FOR A MAGNETIC RESONANCE IMAGING SYSTEM

(71) Applicant: Siemens Aktiengesellschaft, Muenchen (DE)

(72) Inventor: David Grodzki, Erlangen (DE)

(73) Assignee: SIEMENS AKTIENGESELLSCHAFT, Erlangen (DE)

(21) Appl. No.: 14/335,118

(22) Filed: Jul. 18, 2014

(30) Foreign Application Priority Data
Jul. 23, 2013 (DE) 102013214356.7

(51) Int. Cl. G01R 33/56

(52) U.S. Cl. CPC G01R 33/5608; G01R 33/54
USPC 702/123

(57) ABSTRACT

In a method for optimization of a pulse sequence for a magnetic resonance imaging apparatus, a plan gradient pulse train that is to be executed to chronologically match a radio-frequency pulse train to control an RF transmission system of the magnetic resonance imaging apparatus is adopted to control a gradient system of the magnetic resonance imaging apparatus. The determined plan gradient pulse train forms an optimization segment and for the optimization segment a plan gradient moment is determined. A real gradient pulse train that can actually be executed is determined for the optimization segment of the determined plan gradient pulse train and a real gradient moment is determined for the real gradient pulse train. An error gradient moment difference between the real gradient moment and the plan gradient moment is determined. The real gradient pulse train is modified so that the magnitude of the gradient moment difference between the plan gradient moment and the gradient moment of the modified real gradient pulse train is optimized. A pulse sequence optimization unit is designed to implement such a method and a magnetic resonance imaging system is operated using such a pulse sequence optimization unit.

### BACKGROUND OF THE INVENTION

1. Field of the Invention

The invention concerns a method to optimize a pulse sequence for a magnetic resonance imaging system as well as a method to operate a magnetic resonance imaging system using such an optimized pulse sequence, as well as a pulse optimization unit and a magnetic resonance imaging system that are operated using such a method.

2. Description of the Prior Art

In a magnetic resonance apparatus (also called a magnetic resonance tomography system or magnetic resonance imaging system) the subject to be examined is typically exposed to a relatively high basic magnetic field—of 1, 5, 3 or 7 Tesla, for example—with a basic field magnet system. A magnetic field gradient is additionally applied with a gradient system. Radio-frequency excitation signals (RF signals) are then emitted via a radio-frequency transmission system, which cause nuclear spins of specific atoms, excited to resonance by this radio-frequency field, to be deflected or flipped by a defined flip angle relative to the magnetic field lines of the basic magnetic field. Upon relaxation of the nuclear spins, radio-frequency signals (known as magnetic resonance signals) are emitted by the nuclei that are received by suitable reception antennas and are then processed further. Finally, the desired image data can be reconstructed from the raw data acquired in such a manner.

For a specific measurement (data acquisition), a defined pulse sequence is emitted that is composed of a series of radio-frequency pulses, in particular excitation pulses and refocusing pulses, as well as gradient pulses activated in different spatial directions in coordination with the RF pulses. Readout windows that are coordinated in timing must be activated so as to provide time periods in which the induced magnetic resonance signals are acquired. The timing within the sequence—i.e. at which time intervals each pulse follows another—is significant for the imaging. A number of control parameters are normally defined in a set of commands known as a measurement protocol, which is created in advance and that can be retrieved (from a memory, for example) for a specific measurement, and can be modified as necessary on site by the operator who can predetermine additional control parameters, for example a defined slice interval of a stack of slices from which MR signals are to be acquired, a slice thickness, etc. A pulse sequence (that is also designated as a measurement sequence) is then calculated on the basis of all of these control parameters.

The gradient pulses are defined by their gradient amplitude, the gradient pulse time duration and the edge steepness, i.e. the first time derivative of the pulse shape (dG/dt) of the gradient pulses (also typically designated as a “slew rate”). An additional important gradient pulse value is the gradient pulse moment (also shortened to “moment”), which is defined by the integral of the amplitude over time.

During a pulse sequence, individual gradient coils (from which the gradient pulses are emitted) of the gradient system are activated frequently and quickly. Since the time specifications within a pulse sequence are very strict, and additionally since the total duration of a pulse sequence (that defines the total duration of an MRT examination) must be kept as short as possible, gradient strengths around 40 mT/m and slew rates of up to 200 mT/m/ms must be achieved for at least some of the gradient pulses. Such a high slew rate (edge steepness) contributes to the known noise development during the switching of the gradients. Eddy currents with other components of the magnetic resonance scanner (such as the radio-frequency shield) are one reason for these noise disturbances. In addition, steep edges of the gradients lead to a higher power consumption and impose greater requirements on the gradient coils and the additional hardware. The rapidly changing gradient fields lead to distortions and oscillations of these energies at the housing of the cryomagnet that is typically used to generate the strong basic field. A high helium boil-off can additionally occur due to heating of the coils and the additional components.

In order to reduce this noise disturbance, various solutions have been proposed in the design of the hardware, for example potting or vacuum-sealing of the gradient coils.

Moreover, methods are also known that optimize the gradient parameters in a pulse sequence in order to reduce the noise development. For example, within a time segment of a gradient pulse sequence it can be established whether a gradient parameter may be modified for noise reduction for this segment. The optimized segments then most often include a gradient pulse sequence that falls far below the system limits of the gradient system of the magnetic resonance imaging apparatus, such that inaccuracies occur only rarely in the control of the gradient system. Nevertheless, it cannot be precluded that deviations relative to an expected gradient moment will occur even for such optimized pulse sequences.

### SUMMARY OF THE INVENTION

An object of the present invention is to provide a method for optimization of a pulse sequence for a magnetic resonance imaging apparatus wherein deviations of the type described above are minimized. A further object of the present invention is to provide a pulse optimization unit that operates according to such a method, as well as a magnetic resonance imaging apparatus that embodies such a pulse optimization unit.

According to the invention, in a method for optimization of a pulse sequence for a magnetic resonance imaging apparatus, a plan gradient pulse train that is to be executed to chronologically match a radio-frequency pulse train to control the RF transmission system of the magnetic resonance imaging apparatus is initially adopted to control the gradient system of the magnetic resonance imaging system. The adopted plan gradient pulse train has an optimization segment that forms the basis of the subsequent optimization. For this optimization segment, a plan gradient moment is determined that has been generated according to the optimization segment upon control of the gradient system without deviation from the plan gradient pulse train. A real gradient pulse train that can actually be executed is also determined for the optimization segment of the adopted plan gradient pulse train.

For the real gradient pulse train, a real gradient moment is also determined, and subsequently an error gradient moment difference between real gradient moment and plan gradient moment. Furthermore, in the method according to the invention the real gradient pulse train is modified so that the magnitude of the gradient moment difference between the plan gradient moment and the gradient moment of the modified real gradient pulse train is optimized. An optimization in the sense of the invention means that a check is made at least as to whether the gradient moment difference modified according to a rule falls below the previously determined error gradient moment difference. Therefore, a step in which a check is made as to whether a reduction of the gradient moment difference is necessary at all, or is possible in the real gradient pulse train segment, can also be considered as a modification.

For example, the modification can be repeated until the magnitude of the gradient moment difference between plan gradient moment and gradient moment of the modified real gradient pulse train is smaller than a predetermined difference limit value and/or until a maximum number of repetitions is reached. The maximum number of repetitions can in particular be predetermined to be equal to one. For example, a check can also be made as to whether an improvement—i.e. a reduction of the gradient moment difference relative to a preceding pass of the modification—is achieved. If no improvement is achieved, the method can be terminated. In particular, by specifying a difference limit value it can be achieved that the agreement of the actual generated gradient moment (i.e. of a modified real gradient moment) with a plan gradient moment is ensured at a defined quality.

This is particularly effective if the adopted plan gradient pulse train corresponds to what is known as an event block as it is described in DE 10 2013 202 559. Methods described therein can be understood as a basic optimization of the control sequence with regard to a noise optimization, and thus the output data of this method can be used as input data of the present invention.

Because the deviation of an actually generated real gradient moment is kept within specific limits, a defined functionality can be guaranteed for each of the event blocks according to the possible basic optimization.

The invention also concerns a pulse sequence optimization unit to optimize a pulse sequence for a magnetic resonance imaging system. The pulse sequence optimization unit has a plan pulse interface to accept the plan gradient pulse train. The plan gradient pulse train can be formed by one of the aforementioned event blocks. The pulse sequence optimization unit also has a plan moment determination unit that is designed to determine the aforesaid plan gradient moment for the optimization segment of the determined plan gradient pulse train.

For example, the determination of the aforesaid real gradient pulse train can take place so that the optimization segment is sent to a device to execute the gradient pulse train, or to a software and/or hardware emulation of this device, and then the control signals that have really been sent to the gradient coils are determined or, respectively, recorded. This means that the determination of the real gradient pulse train can take place in a real pulse determination unit that is designed to determine a real gradient pulse train that can actually be executed for the optimization segment of the determined plan gradient pulse train.

Moreover, the pulse sequence optimization unit comprises a real moment determination unit to determine a real gradient moment for the real gradient pulse train.

The determined plan gradient moment and the real gradient moment can be used in a gradient moment difference determination unit to determine an error gradient moment difference between real gradient moment and plan gradient moment, which gradient moment difference determination unit is likewise comprised in the pulse sequence optimization unit.

A pulse modification unit of the pulse sequence optimization unit that is designed to modify the real gradient pulse train operates based on the error gradient moment difference.

As mentioned, the modification takes place according to a predetermined rule, in particular such that the magnitude of the gradient moment difference is optimized between plan gradient moment and the gradient moment of the real gradient pulse train to be modified, meaning that the magnitude of the gradient moment difference falls below the magnitude of the determined error gradient moment difference.

The invention also includes a magnetic resonance imaging apparatus with such a pulse sequence optimization unit, as well as a method to operate a magnetic resonance imaging apparatus wherein a pulse sequence is initially optimized with the method according to the invention, and then the magnetic resonance imaging system is operated using such an optimized pulse sequence.

Significant portions of the pulse sequence optimization unit preferably are realized in the form of software on a suitable programmable computer (for example a medical imaging system or magnetic resonance imaging apparatus or a terminal) with appropriate storage capabilities. The interfaces—in particular the plan pulse interface—can, for example, be multiple interfaces that allow the data to be selected or accepted from a data store arranged within the medical imaging system or connected with this via a network, possibly also using a user interface. Furthermore, the systems can have output interfaces in order to pass the generated data to other devices for further processing, presentation, storage etc. A realization (in particular of the pulse sequence optimization unit) largely in software has the advantage that pulse sequence optimization units or medical imaging systems or the like that have previously been in use can be upgraded simply through a software update in order to operate in the manner according to the invention.

Thus, the invention also encompasses a non-transitory, computer-readable storage medium encoded with programming instructions that, for example, can be stored in a portable memory and thus can be loaded directly into one or more memories of the magnetic resonance imaging apparatus and/or the pulse sequence optimization unit. The programming instructions are program code segments in order to execute all steps of the method according to the invention when the overall program is executed in the suitable programmable computer. For example, the computer can be a component of the magnetic resonance imaging apparatus and/or of the pulse sequence optimization unit. The storage medium can be a non-volatile memory.

In an embodiment, the real gradient pulse train can be formed by a number of control segments, wherein a defined curve of a gradient magnetic field which would be generated given use of the control segment in the gradient system is respectively provided for each of the control segments. This means that the control segment provides a real, executable control signal for the gradient system.

For example, the defined curve can be linear, in particular constant. The control signal is preferably linear on a segment-by-segment basis in the overall consideration of the control segments. This means that it is a control signal that can easily be generated by a machine.

This can be the case especially if the control segments coincide with a multiple (which can be equal to one) of a base clock of the magnetic resonance imaging apparatus, which multiple is divided by a whole-number divisor (in particular greater than one). For example, this can be a system clock (generated in this manner) for the generation of a control signal for the gradient system, and each of the control segments can have a constant control signal that, for example, is provided for a defined clock interval.

A gradient moment that would be generated using the control segment in the gradient system can thus be allocated to each of the control segments.

At least two of the control segments differ with respect to a control parameter that, for example, can be a current value for control of the gradient system. This means that the at least two control segments differ in their allocated or generated gradient moment.

The optimization or modification of the real gradient pulse train takes place so that the gradient moment that is generated using multiple control segments is modified. In particular, the modification rule can be such that at least one control segment is thereby modified by a different modification magnitude of a gradient moment than another of the modified control segments. The duration of the control segments is respectively kept constant.

This means that it is preferably not a uniform correction but rather a non-uniform correction of the error gradient moment difference that takes place. A “weighted modification” of the associated or allocated gradient moments of more than one of the control segments preferably takes place. This can be utilized such that jumps or discontinuities in the workflow of control parameters of the gradient magnetic field or of the control signal of the gradient system can be avoided.

The respective modification magnitude of a control segment can be determined by combining of the error gradient moment difference with an allocation function. The allocation function establishes the association of the modification magnitude of the gradient moment with individual control segments via distribution of the determined error gradient moment difference to the individual control segments. For example, a weighting of the error gradient moment difference can take place with a Gaussian function F(t), wherein the variable t which establishes the allocation corresponds to a time variable which reflects the chronological order of the modified control sequences. “Corresponds” in this case means that the cited time variables are possibly scaled relative to one another and/or are shifted so that they can be transformed into one another with a linear function.

In particular, the allocation function can be designed so that a middle (in terms of chronology) control segment in the chronological sequence of the control segments is modified by a greater modification magnitude of the gradient moment than the control segments placed (in terms of chronology) at an edge region of the optimization segment. The noted advantage of avoiding discontinuities can thus be further improved.

In a further embodiment, a pulse modification unit that is designed to use the allocation function to associate a modification magnitude of the error gradient moment with individual control segments of the real gradient pulse train.

In another embodiment of the invention, a number of control segments whose respective gradient moment is modified can be determined for modification or optimization of the real gradient pulse train on the basis of the determined error gradient moment difference. This number of control segments does not need to coincide with the total number of control segments of the real gradient pulse train, which can be predetermined by the system clock in the noted manner, for example. The number of modified control segments can be a minimum number of modified control segments or also the total number of modified control segments that can be associated with the optimization segment.

For example, the number of control segments whose respective gradient moment is modified can be determined using a combination of the error gradient moment difference with a predetermined moment change limit value. For example, the moment change limit value can be determined on the basis of the maximum slew rate. For this purpose, the maximum slew rate can be multiplied by the duration of a control segment in order to determine or form the limit value of the change of the magnetic field. The determined number then corresponds to the error gradient moment difference divided by the moment change limit value, for example. The number then corresponds to a minimum number of control segments whose respective associated gradient moment should be modified so that, with the use of the estimation of the minimum number, for example, a check can be made as to whether it is possible to implement an optimization at all within the predetermined system parameters (i.e. the total number of control segments of the real gradient pulse train and the slew rate).

However, the moment change limit value can also be predetermined such that the maximum slew rate is weighted with a scaling factor based on the allocation function.

Inasmuch, the pulse modification unit can also be designed to determine a number of control segments whose respective gradient moment should be modified.

As noted, the number can be the minimum number of control segments to be modified, but also the total number of control segments of the real gradient pulse train that are to be modified.

### BRIEF DESCRIPTION OF THE DRAWINGS

FIG. 1 shows an exemplary embodiment of a magnetic resonance imaging system according to the invention.

FIG. 2 shows the time curve of a plan gradient pulse train and of a real gradient pulse train determined for the plan gradient pulse train before the optimization according to the invention.

FIG. 3 shows an exemplary embodiment for the distribution of an error gradient moment difference to individual control segments of the real gradient pulse train.

FIG. 4 shows an example of a real gradient pulse train optimized (i.e. modified) according to the invention.

FIG. 5 is a flowchart of an exemplary embodiment of an optimization method according to the invention.

### DESCRIPTION OF THE PREFERRED EMBODIMENTS

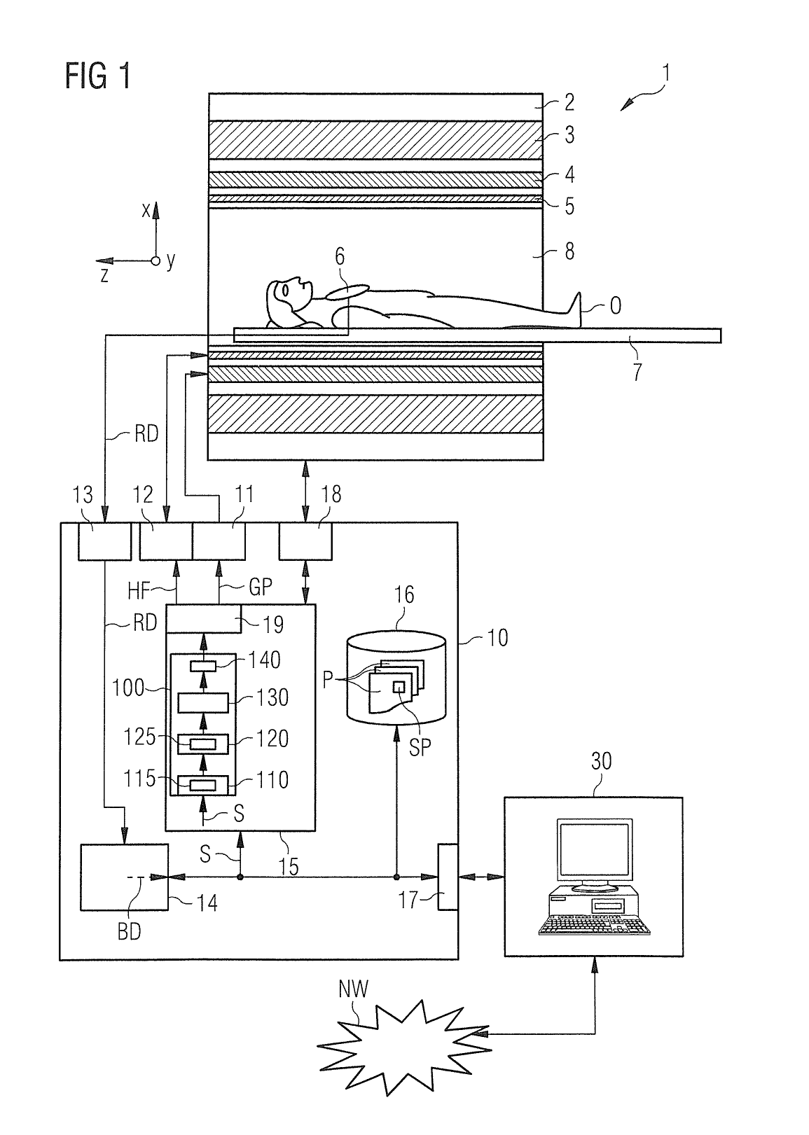

A magnetic resonance imaging apparatus 1 according to the invention is schematically shown in FIG. 1. The apparatus 1 includes the actual magnetic resonance scanner 2 with an examination space or patient tunnel located therein. A bed 7 can be driven into this patient tunnel 8, such that a patient O or test subject lying on the bed 7 can be supported at a defined position within the magnetic resonance scanner 2 relative to the magnet system and radio-frequency system arranged therein during an examination, or can be moved between different positions during a measurement.

Essential components of the magnetic resonance scanner are a basic magnetic field 3, a gradient system 4 with magnetic field gradient coils to generate magnetic field gradients in the x-, y- and z-direction, and a whole-body radio-frequency coil 5. The magnetic field gradient coils can be controlled independently of one another in the x-, y- and z-directions so that gradient magnetic fields or gradients can be applied in arbitrary logical spatial directions (for example in the slice-selection direction, in the phase coding direction or in the readout direction) via a predetermined combination; these directions normally depend on the selected slice orientation. The logical spatial directions can likewise also coincide with the x-, y- and z-directions, for example the slice selection direction in the z-direction, the phase coding direction in the y-direction and the readout direction in the x-direction. The reception of magnetic resonance signals induced in the examination subject O can take place via the whole-body coil 5 with which the radio-frequency signals are normally also emitted to induce the magnetic resonance signals. However, these signals are typically received with a local coil arrangement 6 with (for example) local coils (of which only one is shown here) placed on or below the patient O. All of these components are known in principle to those skilled in the art and therefore are only schematically presented in FIG. 1.

The components of the magnetic resonance scanner 2 are controlled by a control device 10. This can be a control computer, which can be composed of a number of individual computers (which possibly are spatially separated and connected among one another via suitable cables or the like). This control device 10 is connected via a terminal interface 17 with a terminal 30 via which an operator can control the entire system 1. In the present case, this terminal 30 (as a computer) is equipped with keyboard, one or more monitors and additional input devices (for example mouse or the like) so that a graphical user interface is provided to the operator.

Among other things, the control device 10 has a gradient control unit 11 that can include multiple sub-components. Via this gradient control unit 11, the individual gradient coils are connected with control signals according to a gradient pulse sequence GS. As describe above, these are gradient pulses that are placed at precisely provided time positions and with a precisely predetermined time curve during a measurement.

The control device 10 also has a radio-frequency transmission unit 12 in order to feed respective radio-frequency pulses into the whole-body radio-frequency coil 5 according to a predetermined radio-frequency pulse train RF of the pulse sequence S. The radio-frequency pulse sequence RF includes the excitation and refocusing pulses mentioned above. The reception of the magnetic resonance signals then occurs with the aid of the local coil arrangement 6, and the raw data RF received from this, are read out and processed by an RF reception unit 13. The magnetic resonance signals are passed in digital form as raw data RD to a reconstruction unit 14, which reconstructs the image data BD from these and stores them in a memory 16 and/or passes them via the interface 17 to the terminal 20 so that the operator can view them. The image data BD can also be stored at other locations via a network NW and/or be displayed and evaluated. Alternatively, a radio-frequency pulse sequence can be emitted via the local coil arrangement and/or the magnetic resonance signals can be received by the whole-body radio-frequency coil (not shown), depending on the current wiring of the whole-body radio-frequency coil 5 and the coil arrays 6 with the radio-frequency transmission unit 12 or, respectively, RF reception unit 13.

Control commands are transmitted via an additional interface 18 to other components of the magnetic resonance scanner 2 (such as the bed 7 or the basic field magnet 3, for example), or measurement values or, respectively, other information are obtained.

The gradient control unit 11, the RF transmission unit 12 and the RF reception unit 13 are controlled, coordinated respectively, by a measurement control unit 15. Via corresponding commands, this ensures that the desired gradient pulse sequences GS and radio-frequency pulse sequences RF are emitted. Moreover, for this it must be ensured that the magnetic resonance signals are read out at the local coils of the local coil arrangement 6 by the RF reception unit 13 at the appropriate point in time and are processed further. The measurement control unit 15 likewise controls the interface 18. For example, the measurement control unit 15 can be made up of a processor or multiple interacting processors. A pulse sequence determination device 100 according to the invention can be implemented on said processor, for example in the form of suitable software components, which is explained in detail later.

However, the fundamental workflow of such a magnetic resonance measurement and the cited components to control it (apart from the pulse sequence determination unit 100) are known to those skilled in the art, such that further details are not necessary herein. Moreover, such a magnetic resonance scanner 2 and the associated control device can have further components that are likewise not explained in detail herein. The magnetic resonance scanner 2 can be designed differently—for example with a laterally open patient space, or as a smaller scanner in which only one body part is positioned.

In order to start a measurement, via the terminal 30 an operator typically selects a control protocol P provided for this measurement from a memory 16 in which a number of control protocols P for different measurements are stored. Among other things, this control protocol P includes various control parameters SP for the respective measurement. Among these control parameters are specific basic rules for the desired pulse sequence, for example the sequence type (i.e. whether it is a spin echo sequence, a turbo spin echo sequence, etc.). Also among these control parameters are control parameters that define or set the magnetizations of the nuclear spins that are desired to be achieved by the individual radio-frequency pulses, rules defining a k-space gradient trajectory to be traveled in k-space in order to enter acquired raw data into k-space, as well as parameters defining or setting slice thicknesses, slice intervals, number of slices, resolution, repetition times, the echo times in a spin echo sequence, etc.

With the use of the terminal 30, the operator can modify some of these control parameters SP in order to create an individual control protocol P for a currently desired measurement. For this purpose, variable control parameters SP are offered for modification in a graphical user interface of the terminal 30, for example.

Moreover, via a network NW the operator can retrieve control protocols (for example from a manufacturer of the magnetic resonance apparatus) and then possibly modify and use these protocols.

A pulse sequence S or measurement sequence is then determined based on the control parameters SP, with which the actual control of the remaining components ultimately takes place via the measurement control unit 15. The pulse sequence S can be calculated in a pulse sequence determination device, which can be realized in the form of software components at the computer of this terminal 30, for example. In principle, however, the pulse sequence determination device can be part of the control device 10 itself, in particular of the measurement control unit 15. However, the pulse sequence determination device could also similarly be realized at a separate computer system which is connected with the magnetic resonance system via the network NW, for example.

Upon execution of a pulse sequence S, this is supplied via a pulse transmission arrangement 19 of the measurement control unit 15, which ultimately passes the radio-frequency pulse sequence RF to the RF transmission unit 12 and the gradient pulse train GS to the gradient control unit 11, initially in an event block optimization unit (not shown) which, for example, can operate according to a pulse sequence optimization device that is described in the application document of the aforementioned basic optimization with regard to the noise exposure. A spline interpolation of the gradient pulse train is thereby determined under consideration of the four boundary conditions: duration, gradient moment, start point and end point of the gradient. The start point and end point in time can in particular be with regard to what are known as event blocks, as are described in De 10 2013 202 559. The event blocks that are taken into account are transmitted to the pulse sequence optimization device 100 according to the invention and are optimized in the manner according to the invention. For this purpose, pulse sequence optimization device 100 includes a plan pulse interface 110 in order to accept the actual finished pulse sequence S with a plan gradient pulse train, which pulse sequence S is ready for transmission except for the optimization according to the invention.

To execute the plan gradient pulse train, the interpolated spline of the plan gradient pulse train would be “saved” at a raster time (i.e. the system clock) of the gradient system 4 (typically 10 μs), i.e. it is divided into control segments corresponding to the system clock. Deviations from the intended gradient moment of the plan gradient pulse train (i.e. the plan gradient moment) can arise in the percentile range. The pulse sequence optimization device 100 optimizes these control segments according to the invention so that these deviations are largely avoided. The pulse sequence optimization device 100 is accordingly preferably arranged as shown in an “end tail” or “end of pipe” of the system to execute gradient pulse trains GS, i.e. as a “last optimization device” before the pulse sequence arrangement 19.

To optimize the control segments, the pulse sequence optimization device 100 has a real pulse determination unit 120 that, on the basis of an optimization segment of the plan gradient pulse train, determines a real gradient pulse train that can be executed by the gradient system 4. In particular, in this exemplary embodiment the plan gradient pulse train is adopted in the form of the aforementioned event blocks with which a dedicated functionality is respectively associated.

In this exemplary embodiment, the optimization segment coincides with the gradient pulse train of one of the adopted event blocks so that it is ensured that the gradient moment is optimized with regard to a defined functionality of said event block. It is not significant whether the noted basic optimization could already be implemented for the event block. It can also be an event block that cannot be optimized with the noted method for basic optimization. The plan gradient pulse train in this exemplary embodiment is considered to be a “ground rule”, thus as intended for execution.

With the use of a plan moment determination unit 115, a plan gradient moment is also determined for the optimization segment of the plan gradient pulse train, and moreover a real gradient moment is calculated after determination of the real gradient pulse train using a real moment determination unit 125. The real gradient moment is determined for the segment of the real gradient pulse train that corresponds to the optimization segment of the plan gradient pulse train.

In a gradient moment difference determination unit 130, an error gradient moment difference is then determined between the real gradient moment and the plan gradient moment.

This error gradient moment difference is then communicated to a pulse modification unit 140, advantageously together with the real gradient pulse train. In the pulse modification unit it is then established whether an additional optimization of the real gradient pulse train can or must take place. For this purpose, a check can be made as to whether the magnitude of the error gradient moment difference is less than a predetermined difference limit value.

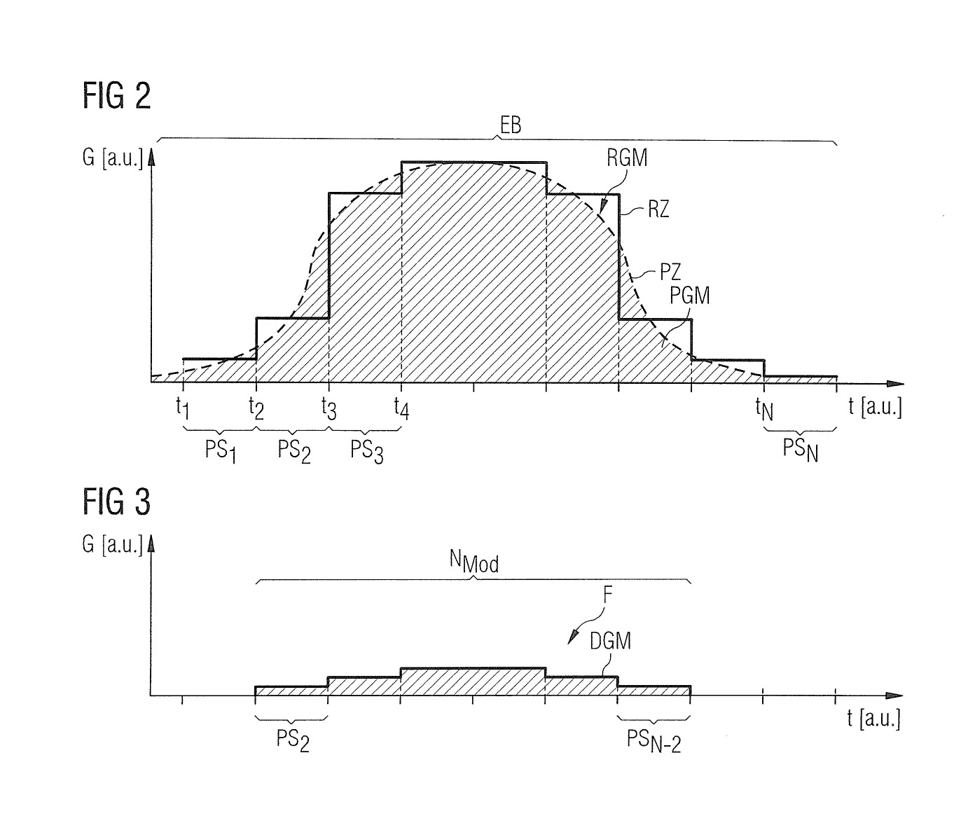

The precise functionality of these components is presented in the following using FIGS. 2 through 5 in the example of a generation and further processing of a pulse sequence S, up to the execution (emission of the radio-frequency pulses and application of the gradients, as well as activation of the reception devices) by the pulse transmission arrangement 19.

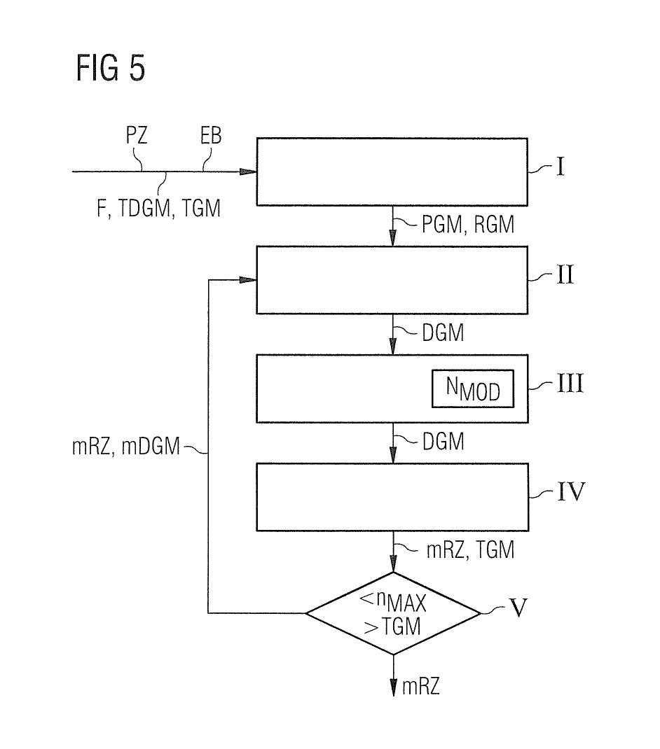

The flowchart shown in FIG. 5 gives an overview of the method.

FIG. 2 shows the gradient pulse train of an event block that forms an optimization segment EB of a plan gradient pulse train PZ. For example, this event block could correspond to the event block designated with EBA₆ in the description of the basic optimization, and the optimization segment EB could in particular be formed by a gradient pulse train for a gradient magnetic field (Gz) in the z-direction. For execution, this plan gradient pulse train PZ is—as mentioned—transmitted in the form of a real gradient pulse train RZ to the pulse transmission arrangement, i.e. the gradient system.

The real gradient pulse train RZ determined for execution has control segments PS₁, PS₂, PS₃ . . . PS_{N} that respectively represent a digitized control value (a current value, for example) for the gradient system that is transmitted to the gradient system or, respectively, the pulse transmission arrangement 19 in a system clock of the magnetic resonance imaging system. The control segments PS₁, PS₂, PS₃ . . . PS_{N}—i.e. the node points of the digitization, respectively between a first point in time t₁, t₂, t₃, t₄, . . . , t_{N} and a second point in time t₂, t₃, t₄, . . . , t_{N}, t_{N+1}—are schematically depicted in this and additional Figures; in reality, the system clock for the gradient system is situated so that a much larger number of control segments PS₁, PS₂, PS₃ . . . PS_{N} would be determined for execution of the shown optimization segment EB (the system clock is most often approximately 100 kHz, and the optimization segment EB most often has a duration of a few milliseconds).

As can be seen from FIG. 5, the determination of the real gradient pulse train RZ is included in a first step I of the optimization method. In addition to the plan gradient pulse train PZ with the optimization segment EB, which is preferably adopted as a spline pulse train after a basic optimization has taken place, for the optimization method a series of optimization parameters is provided that can be used in each step of the optimization method. The depiction of the relaying of these optimization parameters in the relevant method steps I, II, III, IV, V of FIG. 5 was omitted for reasons of clarity. In particular, the optimization parameters are what are known as an allocation function F, a difference limit value TGM and a moment change limit value TDGM, whose use in the respective relevant method steps will be explained in detail.

As can be seen by the curve of the real gradient pulse train RZ that is shown in FIG. 2, this can serve as a control signal for a current that flows through the gradient coils of the gradient system. The gradient coils then generate a gradient magnetic field G traveling proportional to this control signal.

The time sequence of the control segments PS₁, PS₂, PS₃ . . . PS_{N} is shown in a diagram in FIG. 2, which shows the gradient magnetic field G in arbitrary units (a. u.) on the vertical axis and the time t in arbitrary units on the horizontal axis.

Each of the control segments PS₁, PS₂, PS₃ . . . PS_{N} corresponds to a time interval with constant length of approximately 10 μs, and a linear constant control signal for the gradient system is associated with each of the control segments PS₁, PS₂, PS₃ . . . PS_{N}. The control signals of the control segments PS₁, PS₂, PS₃ . . . PS_{N} in combination form the real gradient pulse train RZ that is associated with the optimization segment EB of the plan gradient pulse train PZ.

The real gradient pulse train RZ generates a gradient moment RGM for the time period of the optimization segment EB which, according to the depiction, is at least proportional to the area between transversal axis (t) and real gradient pulse train RZ (first order gradient moment). The real gradient moment should optimally be tantamount to a plan gradient moment PGM (shaded in the depiction, first order gradient moment) which is likewise determined for the time period of the optimization segment EB.

In the exemplary embodiment of the optimization method as shown in FIG. 5, this real gradient moment RGM and the associated plan gradient moment PGM are determined in method step I.

As can be seen from the stepped curve of the real gradient pulse train RZ in FIG. 2, given this type of control it is not guaranteed that the generated real gradient moment RGM coincides with a plan gradient moment PGM of the plan gradient pulse train PZ.

Here the method according to the invention achieves an improvement.

In step II (FIG. 5) of the shown exemplary embodiment, an error gradient moment difference DGM is determined, i.e. the difference between plan gradient moment PGM and real gradient moment RGM. If the plan gradient moment PGM is greater than or equal to the real gradient moment RGM, the difference value is positive; otherwise it is negative. This means that the error gradient moment difference DGM determined in this way can be directly used as a correction value for the real gradient moment RGM.

For example, using this correction value (i.e. the error gradient moment difference DGM) it can already be estimated whether a modification of the real gradient pulse train RZ (i.e. an optimization) can be implemented. In particular, a permissible slew rate (i.e. the rise per time of the current through the gradient coils) should not be exceeded in the control of the gradient system. For example, for this the noted moment change limit value TDGM can be formed by the product of slew rate and time per control segment PS₁, PS₂, PS₃ . . . PS_{N}.

With the aid of a moment change limit value TDGM calculated in such a manner, a number of control segments N_{Mod} that are at least to be modified can be determined in that the magnitude of the error gradient moment difference DGM is divided by the magnitude of the moment change limit value TDGM. In the shown exemplary embodiment, this takes place in step III.

If the number of control segments N_{Mod} that are at least to be modified falls below the total number N of control segments PS₁, PS₂, PS₃ . . . , PS_{N} of the real gradient pulse train RZ, it is to be expected that an optimization of the real gradient pulse train can be implemented. Otherwise, the quality of the optimization can be questionable, and the method can optionally already be terminated at this point. The real gradient pulse train RZ is then transmitted to the pulse transmission arrangement.

FIG. 3 shows an error gradient moment difference DGM that can occur between the plan gradient moment PGM and the real gradient moment RGM for the optimization segment EB shown in FIG. 2. The error gradient moment difference DGM is thereby distributed with the allocation function F to a number NMod of modified control segments, such that in total essentially the error gradient moment difference DGM relative to the original real gradient moment RGM is additionally generated over the course of the modified control segments.

In the shown exemplary embodiment, the allocation function that establishes the time curve of the allocation of the error gradient moment difference DGM to control segments, for instance in a triangle function (isosceles) that—viewed in a time period of all modified control segments of the real gradient pulse train—associates a higher proportion of the error gradient moment difference DGM with a chronologically middle segment, for example as control segments placed earlier (i.e. at the beginning) or later (i.e. at the end). It can thus be ensured that no jumps in the control signal of the gradient coils that are too strong occur, and the achieved advantage with regard to the generated gradient moment is brought into question by other disadvantages (for example too high a noise exposure). In a departure from step III, the number of modified control segments N_{Mod} is determined in step IV (FIG. 5) of the method is determined on the basis of the allocation function F in the moment change limit value.

For example, for this the moment change limit value TDGM can be modified with a scaling factor that is predetermined for the allocation function F. As is likewise apparent in FIG. 3, the number N_{Mod} of the modified control segments does not necessarily coincide with the total number N of control segments of the real gradient pulse train. For example, N_{Mod} can be less than N.

In step IV (according to FIG. 5), a modified real gradient pulse train mRZ is then determined on the basis of the determined allocation of the error gradient moment difference DGM.

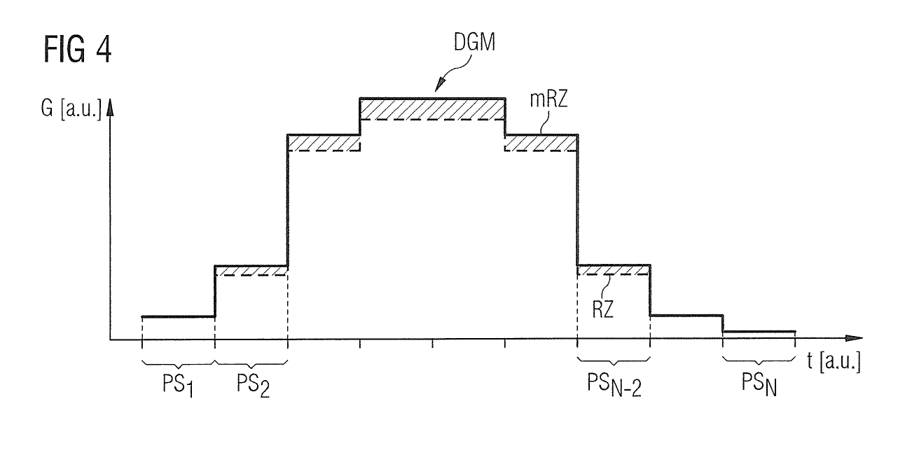

This is shown in detail in FIG. 4. A control signal according to the allocation of the error gradient moment difference DGM as shown in FIG. 3 is added to the control signal according to the control segments PS₁, PS₂, PS₃ . . . , PS_{N} of the real gradient pulse train RZ, such that the modified real gradient pulse train mRZ generates a modified real gradient moment mRGM (FIG. 5) that differs by the error gradient moment difference DGM relative to the real gradient moment.

In the ideal case, an agreement of the modified real gradient moment mRGM with the plan gradient moment PGM can thus be achieved. In reality, however, the step width (i.e. possible roundings that in particular arise due to a digitization) of the control signals that can be generated can have a new deviation of the noted gradient moments as a result. In step V of the method shown in FIG. 5, a check can be made as to whether the magnitude of the deviation of the modified real gradient moment mRGM from the plan gradient moment PGM lies below the difference limit value TGM established as an optimization parameter, such that a desired quality with regard to the generated real gradient moment RGM is ensured. In this case, the modified real gradient pulse train mRZ can be transferred for execution. Otherwise, the modified real gradient pulse train mRZ and the modified real gradient moment mRGM can serve as input parameters for step II of the method according to FIG. 5. A new pass of the method can be started with these input parameters, beginning with step II. In order to avoid endless loops, in step V a check can thereby likewise be made as to whether a maximum number n_{Max} of repetitions has already been reached, and the modified real gradient pulse train mRZ can likewise be supplied for execution before exceeding this number.

From the previous descriptions it is apparent that the invention provides a range of possibilities to minimize (i.e. to optimize) the deviations relative to a gradient moment expected in the execution of a gradient pulse train.

Although modifications and changes may be suggested by those skilled in the art, it is the intention of the inventor to embody within the patent warranted hereon all changes and modifications as reasonably and properly come within the scope of his contribution to the art.

I claim as my invention:

1. A computerized method for optimization of a pulse sequence for operating a magnetic resonance imaging apparatus, comprising:
entering a plan gradient pulse train into a computerized processor, said plan gradient pulse train being configured to control a gradient system of a magnetic resonance imaging apparatus with chronological matching to a radio-frequency (RF) pulse train to control an RF transmission system of the magnetic resonance imaging apparatus, said plan gradient pulse train comprising an optimization segment;
in said computerized processor, determining a plan gradient moment of the optimization segment of the plan gradient pulse train;
in said computerized processor, automatically determining a real gradient pulse train for the optimization segment of the plan gradient pulse train, which is actually executable by said gradient system, by
(a) determining a real gradient moment for said real gradient pulse train,
(b) determining an error gradient moment difference between the real gradient moment and plan gradient moment, and
(c) modifying said real gradient pulse train by optimizing a magnitude of said gradient moment difference; and
making said real gradient pulse train, comprising said optimization segment with the optimized magnitude of the gradient moment difference, available in electronic form at an output of said computerized processor in a format for controlling said gradient system.

2. A method as claimed in claim 1 comprising optimizing said magnitude of said gradient moment difference by repeating (a) through (c) until the magnitude of the gradient moment difference is smaller than a predetermined difference value, or until a maximum number of repetitions of (a) through (c) is reached.

3. A method as claimed in claim 1 comprising determining said real gradient pulse train so as to include a plurality of control segments with a defined curve of a gradient magnetic field produced by said gradient system being respectively predetermined for each of the control segments.

4. A method as claimed in claim 3 wherein said defined curve is linear for each of said control segments, and wherein said plurality of control segments is a whole-number multiple of a base clock of said magnetic resonance imaging apparatus.

5. A method as claimed in claim 3 wherein each of said plurality of control segments has a gradient moment and, in said computerized processor, modifying the respective gradient moments of said control segments.

6. A method as claimed in claim 5 comprising modifying the respective gradient moments of the control segments to give at least one of said control segments a magnitude of said gradient moment that is different than a magnitude of the gradient moment of another of said control segments.

7. A method as claimed in claim 5 wherein each of said gradient moments has a magnitude, and modifying the respective magnitudes of the gradient moments of the respective control segments using a combination of the gradient moment difference with an allocation function that establishes an association of the respective magnitude of the respective gradient moment with others of said control segments by distributing the determined gradient moment difference among the individual control segments.

8. A method as claimed in claim 7 comprising employing, as said allocation function, an allocation function wherein a chronologically middle control segment, among said plurality of control segments, is modified to have a larger magnitude of the gradient moment than control segments chronologically preceding and chronologically following said middle control segment.

9. A method as claimed in claim 5 comprising using a number of said control segments, among said plurality of control segments, for which the respective gradient moment thereof is modified, for modification of said real gradient pulse train based on the gradient moment difference.

10. A method as claimed in claim 9 comprising modifying said real gradient pulse train using said number of control segments combined with a predetermined gradient moment change limit value.

11. A pulse sequence optimization unit that determines a pulse sequence for operating a magnetic resonance apparatus, comprising:
a computerized processor having an input configured to receive a plan gradient pulse train, said plan gradient pulse train being configured to control a gradient system of a magnetic resonance imaging apparatus with chronological matching to a radio-frequency (RF) pulse train to control an RF transmission system of the magnetic resonance imaging apparatus, said plan gradient pulse train comprising an optimization segment;
said computerized processor comprising a pulse modification unit configured to determine a plan gradient moment of the optimization segment of the plan gradient pulse train;
said pulse modification unit being configured to automatically determine a real gradient pulse train for the optimization segment of the plan gradient pulse train, which is actually executable by said gradient system, by
(a) determining a real gradient moment for said real gradient pulse train,
(b) determining an error gradient moment difference between the real gradient moment and plan gradient moment, and
(c) modifying said real gradient pulse train by optimizing a magnitude of said gradient moment difference; and
said computerized processor being configured to make said real gradient pulse train, comprising said optimization segment with the optimized magnitude of the gradient moment difference, available in electronic form at an output of said computerized processor in a format for controlling said gradient system.

12. A pulse sequence optimization unit as claimed in claim 11 wherein said pulse modification unit is configured to use an allocation function to associate a modification magnitude of the gradient moment with individual control segments of said real gradient pulse train.

13. A pulse sequence optimization unit as claimed in claim 12 wherein said pulse modification unit is configured to determine a number of said control segments for which the respective gradient moment thereof is modified.

14. A magnetic resonance apparatus comprising:
a magnetic resonance data acquisition unit comprising a radio frequency (RF) transmission system and a gradient system;
a computerized processor configured to receive therein a plan gradient pulse train, said plan gradient pulse train being configured to control the gradient system of the magnetic resonance data acquisition unit with chronological matching to a radio-frequency (RF) pulse train to control the RF transmission system of the magnetic resonance data acquisition unit, said plan gradient pulse train comprising an optimization segment;
said computerized processor being configured to determine a plan gradient moment of the optimization segment of the plan gradient pulse train;
said computerized processor being configured to automatically determine a real gradient pulse train for the optimization segment of the plan gradient pulse train, which is actually executable by said gradient system, by
(a) determining a real gradient moment for said real gradient pulse train,
(b) determining an error gradient moment difference between the real gradient moment and plan gradient moment, and
(c) modifying said real gradient pulse train by optimizing a magnitude of said gradient moment difference; and
said computerized processor being configured to make said real gradient pulse train, comprising said optimization segment with the optimized magnitude of the gradient moment difference, available in electronic form at an output of said computerized processor in a format for controlling said gradient system.

15. A non-transitory, computer-readable data storage medium encoded with programming instructions, said storage medium being loaded into a computerized processor of a magnetic resonance apparatus, said magnetic resonance apparatus having a magnetic resonance data acquisition unit comprising a radio-frequency (RF) transmission system and a gradient system, and said programming instructions causing said computerized processor to:
receive a plan gradient pulse train, said plan gradient pulse train being configured to control a gradient system of a magnetic resonance imaging apparatus with chronological matching to a radio-frequency (RF) pulse train to control an RF transmission system of the magnetic resonance imaging apparatus, said plan gradient pulse train comprising an optimization segment;
determine a plan gradient moment of the optimization segment of the plan gradient pulse train;
determine a real gradient pulse train for the optimization segment of the plan gradient pulse train, which is actually executable by said gradient system, by
(a) determining a real gradient moment for said real gradient pulse train,
(b) determining an error gradient moment difference between the real gradient moment and plan gradient moment, and
(c) modifying said real gradient pulse train by optimizing a magnitude of said gradient moment difference; and
make said real gradient pulse train, comprising said optimization segment with the optimized magnitude of the gradient moment difference, available in electronic form at an output of said computerized processor in a format for controlling said gradient system.
